(19) United States
(12) Patent Application Publication
(10) Pub. No.: US 2012/0235293 A1
(43) Pub. Date: Sep. 20, 2012

(54) SEMICONDUCTOR DEVICE INCLUDING A BASE PLATE

(75) Inventors: Patrick Jones, Soest (DE); Andre Christmann, Ruethen (DE)

(73) Assignee: INFINEON TECHNOLOGIES AG, Neubiberg (DE)

(21) Appl. No.: 13/048,466

(22) Filed: Mar. 15, 2011

(51) Int. Cl. H01L 23/473; H01L 21/58; H01L 23/34

(52) U.S. Cl. 257/714; 257/712; 438/122; 257/E23.08; 257/E23.098; 257/E21.505

(57) ABSTRACT

A semiconductor device includes a semiconductor chip and a base plate coupled to the semiconductor chip. The base plate includes an upper portion and a lower portion. The upper portion has a bottom surface intersecting a sidewall of the lower portion. The semiconductor device includes a cooling element coupled to the base plate. The cooling element has a first surface directly contacting the bottom surface of the upper portion of the base plate, a second surface directly contacting the sidewall of the lower portion of the base plate, and a third surface parallel to the first surface and aligned with a bottom surface of the lower portion of the base plate.

### BACKGROUND

Power electronic modules are semiconductor packages that are used in power electronic circuits. Power electronic modules are typically used in vehicular and industrial applications, such as in inverters and rectifiers. The semiconductor components included within the power electronic modules are typically insulated gate bipolar transistor (IGBT) semiconductor chips or metal-oxide-semiconductor field effect transistor (MOSFET) semiconductor chips. The IGBT and MOSFET semiconductor chips have varying voltage and current ratings. Some power electronic modules also include additional semiconductor diodes (i.e., free-wheeling diodes) in the semiconductor package for overvoltage protection.

In general, two different power electronic module designs are used. One design is for higher power applications and the other design is for lower power applications. For higher power applications, a power electronic module typically includes several semiconductor chips integrated on a single substrate. The substrate typically includes an insulating ceramic substrate, such as Al₂O₃, AlN, Si₃N₄, or other suitable material, to insulate the power electronic module. At least the top side of the ceramic substrate is metallized with either pure or plated Cu, Al, or other suitable material to provide electrical and mechanical contacts for the semiconductor chips. The metal layer is typically bonded to the ceramic substrate using a direct copper bonding (DCB) process, a direct aluminum bonding process (DAB) process, or an active metal brazing (AMB) process.

Typically, soft soldering with Sn—Pb, Sn—Ag, Sn—Ag—Cu, or another suitable solder alloy is used for joining a semiconductor chip to a metallized ceramic substrate. Typically, several substrates are combined onto a planar metal base plate. In this case, the backside of the ceramic substrate is also metallized with either pure or plated Cu, Al, or other suitable material for joining the substrates to the planar metal base plate. To join the substrates to the planar metal base plate, soft soldering with Sn—Pb, Sn—Ag, Sn—Ag—Cu, or another suitable solder alloy is typically used. The planar metal base plate may in turn be attached to a cooling element through which a coolant may flow to prevent overheating of the power electronic module during operation.

With the increasing desire to use power electronics in harsh environments (e.g., automotive applications) and the ongoing integration of semiconductor chips, the externally and internally dissipated heat continues to increase. Therefore, there is a growing demand for high temperature power electronic modules capable of operating with internal and external temperatures up to and exceeding 200° C. In addition, the current density of power electronics continues to increase, which leads to an increase in the density of power losses. Therefore, liquid cooling of the power electronics via cooling elements to prevent overheating is becoming increasingly important.

For these and other reasons, there is a need for the present invention.

### SUMMARY

One embodiment provides a semiconductor device. The semiconductor device includes a semiconductor chip and a base plate coupled to the semiconductor chip. The base plate includes an upper portion and a lower portion. The upper portion has a bottom surface intersecting a sidewall of the lower portion. The semiconductor device includes a cooling element coupled to the base plate. The cooling element has a first surface directly contacting the bottom surface of the upper portion of the base plate, a second surface directly contacting the sidewall of the lower portion of the base plate, and a third surface parallel to the first surface and aligned with a bottom surface of the lower portion of the base plate.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a cross-sectional view of one embodiment of a semiconductor device.

FIG. 2 illustrates a cross-sectional view of one embodiment of a cooling element.

FIG. 3A illustrates a cross-sectional view of one embodiment of a semiconductor device coupled to a cooling element.

FIG. 3B illustrates a cross-sectional view of another embodiment of a semiconductor device coupled to a cooling element.

FIG. 4A illustrates a cross-sectional view of another embodiment of a semiconductor device coupled to a cooling element.

FIG. 4B illustrates a cross-sectional view of another embodiment of a semiconductor device coupled to a cooling element.

FIG. 5A illustrates a cross-sectional view of another embodiment of a semiconductor device coupled to a cooling element.

FIG. 5B illustrates a cross-sectional view of another embodiment of a semiconductor device coupled to a cooling element.

### DETAILED DESCRIPTION

In the following Detailed Description, reference is made to the accompanying drawings, which form a part hereof, and in which is shown by way of illustration specific embodiments in which the disclosure may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As used herein, the term “electrically coupled” is not meant to mean that the elements must be directly coupled together and intervening elements may be provided between the “electrically coupled” elements.

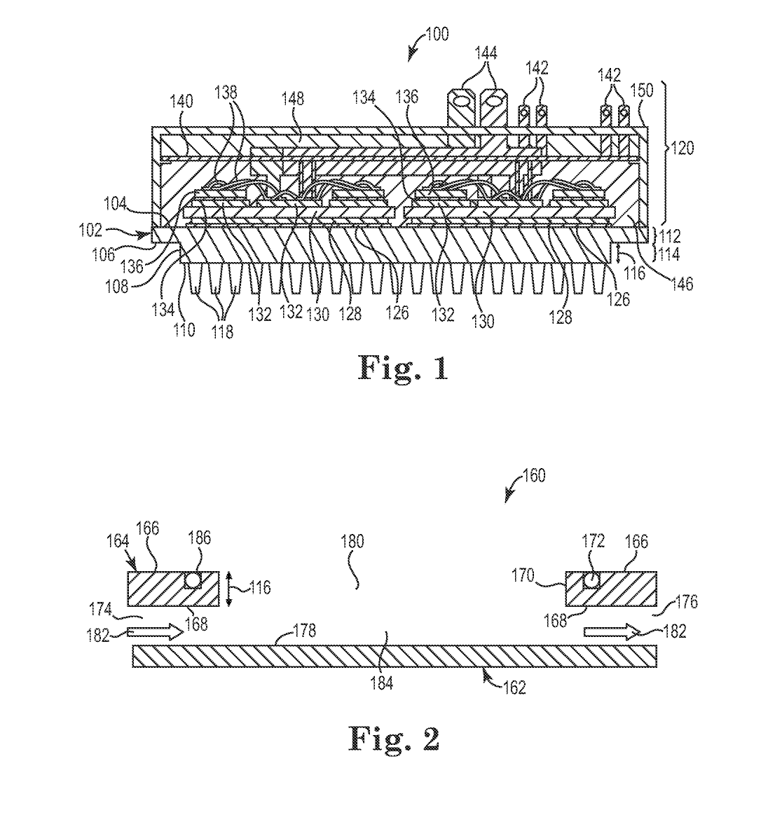

FIG. 1 illustrates a cross-sectional view of one embodiment of a semiconductor device 100. In one embodiment, semiconductor device 100 is a high temperature (i.e., up to and exceeding 200° C.) high power electronic module. Power electronic module 100 includes a metal base plate 102 coupled to a structure 120. Structure 120 includes sintered or soldered joints 126, metalized ceramic substrates 130 including metal surfaces or layers 128 and 132, sintered or soldered joints 134, semiconductor chips 136, bond wires 138, a circuit board 140, control contacts 142, power contacts 144, potting 146 and 148, and a housing 150.

Base plate 102 includes a first or upper portion 112 and a second or lower portion 114. First portion 112 includes a top surface 104 and a bottom surface 106 intersecting a sidewall 108 of second portion 114. In one embodiment, sidewall 108 of second portion 114 has a height 116 such that when base plate 102 is attached to a cooling element, base plate 102 extends into an opening of the cooling element so that a coolant flows linearly passed the base plate. In one embodiment, pins 118 extend from a bottom surface 110 of second portion 114. Pins 118 increase the heat transfer from structure 120 and base plate 102 to a coolant within a cooling element. In another embodiment, pins 118 are excluded. Base plate 102 and pins 118 are made of copper, nickel plated copper, or other suitable material.

Ceramic substrates 130 include Al₂O₃, AlN, Si₃N₄, or other suitable material. In one embodiment, ceramic substrates 130 each have a thickness within a range of 0.2 mm to 2.0 mm. Metal layers 128 and 132 include Cu, Al, or another suitable material. In one embodiment, metal layers 128 and/or 132 are plated with Ni, Ag, Au, and/or Pd. In one embodiment, metal layers 128 and 132 each have a thickness within a range of 0.1 mm to 0.6 mm. Sintered or soldered joints 126 join metal layers 128 to metal base plate 102. Sintered or soldered joints 134 join metal layers 132 to semiconductor chips 136.

Semiconductor chips 136 are electrically coupled to metal layers 132 through bond wires 138. Bond wires 138 include Al, Cu, Al—Mg, Au, or another suitable material. In one embodiment, bond wires 138 are bonded to semiconductor chips 136 and metal layers 132 using ultrasonic wire bonding. Metal layers 132 are electrically coupled to circuit board 140 and power contacts 144. Circuit board 140 is electrically coupled to control contacts 142.

Housing 150 encloses sintered or soldered joints 126, metallized ceramic substrates 130 including metal layers 128 and 132, sintered or soldered joints 134, semiconductor chips 136, bond wires 138, circuit board 140, portions of control contacts 142, and portions of power contacts 144. Housing 150 includes technical plastics or another suitable material. Housing 150 is joined to top surface 104 of metal base plate 102.

Potting material 146 fills areas below circuit board 140 within housing 150 around sintered or soldered joints 126, metallized ceramic substrates 130 including metal layers 128 and 132, sintered or soldered joints 134, semiconductor chips 136, and bond wires 138. Potting material 148 fills the area above circuit board 150 within housing 150 around portions of control contacts 142 and portions of power contacts 144. Potting material 146 and 148 includes silicone gel or another suitable material. Potting material 146 and 148 prevents damage to power electronic module 100 by dielectrical breakdown.

FIG. 2 illustrates a cross-sectional view of one embodiment of a cooling element 160. Cooling element 160 includes a first portion 162 and a second portion 164 attached to first portion 162. A bottom surface 168 of second portion 164 and a top surface 178 of first portion 162 define an inlet 174 and an outlet 176 of the cooling element. Inlet 174 and outlet 176 enable a coolant to flow through a cavity 184 of cooling element 160 as indicated by arrows 182. Sidewalls 170 of second portion 164 define an opening 180 through second portion 164 to cavity 184. Opening 180 is configured to receive the lower portion 114 of base plate 102 previously described and illustrated with reference to FIG. 1. In one embodiment, the height of sidewalls 170 of opening 180 is equal to height 116 of second portion 114 of base plate 102.

A sealant 172 is arranged within a recess 186 in surface 166 of second portion 164. In one embodiment, sealant 172 is an O-ring. Sealant 172 surrounds opening 180 and provides a seal between cooling element 160 and base plate 102 when base plate 102 is attached to cooling element 160. Sealant 172 prevents coolant from leaking between cooling element 160 and base plate 102. In this embodiment, sealant 172 is arranged to contact surface 106 of base plate 102 when base plate 102 is attached to cooling element 160. Sealant 172 is made of silicon, a polymer, or another suitable material.

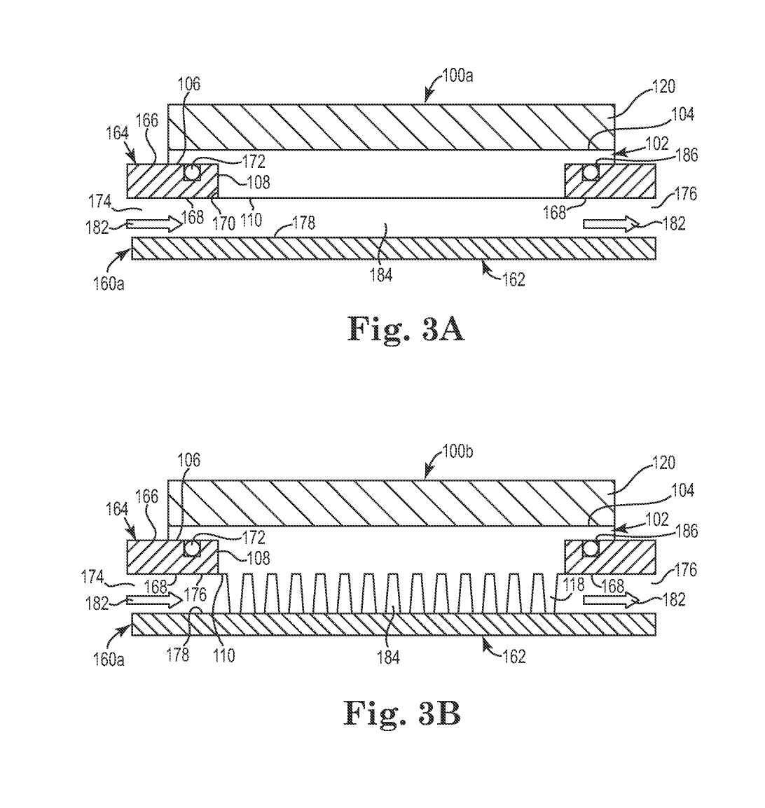

FIG. 3A illustrates a cross-sectional view of one embodiment of a semiconductor device 100a coupled to a cooling element 160a. In one embodiment, semiconductor device 100a includes a structure 120 as previously described and illustrated with reference to FIG. 1. Structure 120 is attached to top surface 104 of base plate 102 as previously described and illustrated with reference to FIG. 1. Base plate 102 is coupled to cooling element 160a, which is similar to cooling element 160 previously described and illustrated with reference to FIG. 2. Base plate 102 is coupled to cooling element 160a using screws or another suitable attachment method.

With base plate 102 coupled to cooling element 160a, surface 106 of base plate 102 contacts surface 166 of cooling element 160a. Surface 106 of base plate 102 also contacts sealant 172. Sidewall 108 of base plate 102 contacts sidewall 170 of cooling element 160a. Due to the matching heights of sidewall 108 of base plate 102 and sidewall 170 of cooling element 160a, bottom surface 110 of base plate 102 is aligned with bottom surface 168 of second portion 164 of cooling element 160a. Thus, bottom surface 110 of base plate 102 and bottom surface 168 of second portion 164 of cooling element 160a define the top of cavity 184. The bottom of cavity 184 is defined by top surface 178 of first portion 162 of cooling element 160a.

Due to the alignment of bottom surface 110 of base plate 102 with bottom surface 168 of second portion 164 of cooling element 160a, inlet 174 and outlet 176 are aligned with cavity 184. As such, a coolant flowing through cooling element 160a flows linearly passed base plate 102. Base plate 102 provides many advantages compared to a conventional planar base plate that consists of only upper portion 112 as previously described and illustrated with reference to FIG. 1.

For example, the linear flow of the coolant enabled by base plate 102 improves the cooling of the entire base plate surface 110 by reducing areas of stagnant coolant near the corners of the base plate that may exist for conventional planar base plates. Due to the alignment of inlet 174, cavity 184, and outlet 176, there is a lower pressure drop through cooling element 160a with base plate 102 compared to a conventional planar base plate. In addition, the alignment of inlet 174, cavity 184, and outlet 176 reduces the chance that air pockets evolve during the filling of cooling element 160a with coolant. To increase the rigidness of base plate 102, material is added in the area of opening 180 of cooling element 160a. This differs from a conventional planar base plate in which the thickness of the entire plate is increased to increase the rigidness. Thus, the volume of material used for base plate 102 may be less than the volume of material used for a conventional planar base plate to achieve the same rigidness. Further, the mass of base plate 102 directly under the electrical components acts as a thermal capacitor that improves the thermal performance of the semiconductor device.

FIG. 3B illustrates a cross-sectional view of another embodiment of a semiconductor device 100b coupled to cooling element 160a. Semiconductor device 100b is similar to semiconductor device 100a previously described and illustrated with reference to FIG. 3A, except that semiconductor device 100b includes pins 118. Pins 118 extend from surface 110 of base plate 102 into cavity 184 of cooling element 160a. In one embodiment, pins 118 contact surface 178 of first portion 162 of cooling element 160a. In other embodiments, pins 118 extend into cavity 184 but do not contact surface 178 of first portion 162 of cooling element 160a.

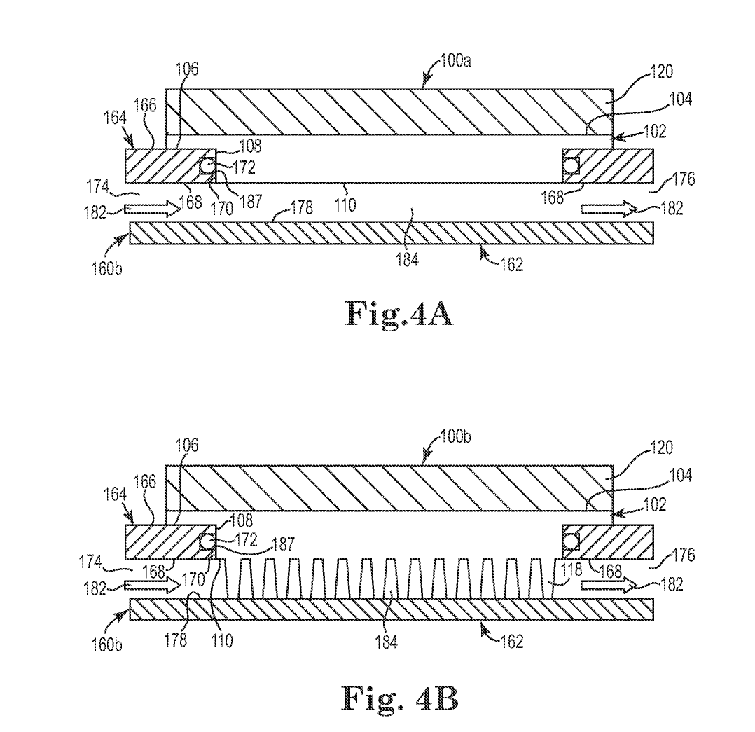

FIG. 4A illustrates a cross-sectional view of another embodiment of semiconductor device 100a coupled to a cooling element 160b. Cooling element 160b is similar to cooling element 160a previously described and illustrated with reference to FIG. 3A, except for the location of sealant 172. In this embodiment, sealant 172 is arranged within a recess 187 in sidewall 170 of second portion 164 of cooling element 160b. Thus, sealant 172 contacts sidewall 108 of base plate 102 to prevent leakage of coolant between base plate 102 and cooling element 160b. FIG. 4B illustrates a cross-sectional view of one embodiment of semiconductor device 100b coupled to cooling element 160b. Semiconductor device 100b is similar to semiconductor device 100a previously described and illustrated with reference to FIG. 4A, except that semiconductor device 100b includes pins 118.

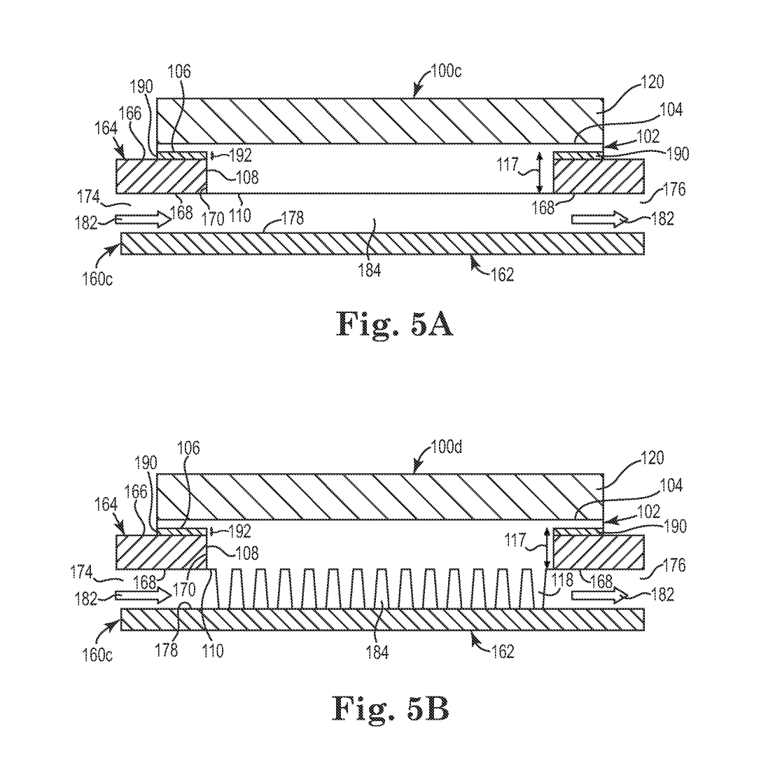

FIG. 5A illustrates a cross-sectional view of another embodiment of a semiconductor device 100c coupled to a cooling element 160c. Cooling element 160c is similar to cooling element 160a previously described and illustrated with reference to FIG. 3A, except that sealant 172 is replaced with sealant 190. In this embodiment, sealant 190 is arranged between surface 106 of base plate 102 and surface 166 of second portion 164 of cooling element 160c. In one embodiment, sealant 190 is a silicon paste or a silicon glue applied to cooling element 160c or base plate 102 prior to coupling base pate 102 to cooling element 160c. In another embodiment, sealant 190 is a gasket made of silicon, a polymer, or another suitable material.

To accommodate sealant 190 and to still provide for the alignment of bottom surface 168 of second portion 164 of cooling element 160c with bottom surface 110 of base plate 102, the second portion of base plate 102 has a height 117 equal to height 116 of sidewall 170 of second portion 164 of cooling element 160c plus a height 192 of sealant 190.

FIG. 5B illustrates a cross-sectional view of another embodiment of a semiconductor device 100d coupled to cooling element 160c. Semiconductor device 100d is similar to semiconductor device 100c previously described and illustrated with reference to FIG. 5A, except that semiconductor device 100d includes pins 118.

Embodiments provide a power semiconductor module including a base plate coupled to a cooling element. The base plate is configured such that when the base plate is attached to the cooling element, a coolant flows linearly through the cooling element and passed the base plate. The linear flow of the coolant passed the base plate improves the thermal performance of the power semiconductor module when compared to power semiconductor modules using conventional planar base plates.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A semiconductor device comprising:
a semiconductor chip;
a base plate coupled to the semiconductor chip, the base plate comprising an upper portion and a lower portion, the upper portion having a bottom surface intersecting a sidewall of the lower portion; and
a cooling element coupled to the base plate, the cooling element having a first surface directly contacting the bottom surface of the upper portion of the base plate, a second surface directly contacting the sidewall of the lower portion of the base plate, and a third surface parallel to the first surface and aligned with a bottom surface of the lower portion of the base plate.

2. The semiconductor device of claim 1, further comprising:
a sealant directly contacting the base plate and the cooling element.

3. The semiconductor device of claim 2, wherein the sealant comprises an O-ring.

4. The semiconductor device of claim 3, wherein the cooling element comprises a recess in the first surface for arranging the O-ring.

5. The semiconductor device of claim 3, wherein the cooling element comprises a recess in the second surface for arranging the O-ring.

6. The semiconductor device of claim 2, wherein the sealant comprises one of a silicon paste and a silicon glue.

7. The semiconductor device of claim 2, wherein the sealant comprises a gasket.

8. The semiconductor device of claim 1, further comprising:
pins extending from the bottom surface of the lower portion of the base plate.

9. The semiconductor device of claim 1, wherein the semiconductor chip comprises a power semiconductor chip.

10. The semiconductor device of claim 1, further comprising:
a substrate coupling the semiconductor chip to the base plate.

11. The semiconductor device of claim 10, wherein the substrate comprises a metallized ceramic substrate.

12. A module comprising:
a power semiconductor chip;
a base plate coupled to the power semiconductor chip; and
a cooling element coupled to the base plate, the cooling element comprising an inlet and an outlet for passing a coolant through the cooling element, the inlet and outlet defined by a first surface of the cooling element;
wherein a first surface of the base plate is aligned with the first surface of the cooling element.

13. The module of claim 12, wherein a second surface of the base plate directly contacts a second surface of the cooling element, the second surface of the cooling element directly opposite the first surface of the cooling element.

14. The module of claim 13, wherein a third surface of the base plate extends from the first surface of the base plate to the second surface of the base plate, the third surface of the base plate directly contacting a third surface of the cooling element.

15. The module of claim 12, further comprising:
a sealant between the base plate and the cooling element, the sealant configured to prevent leakage of the coolant between the base plate and the cooling element.

16. The module of claim 15, wherein the sealant comprises one of an O-ring, a gasket, a silicon paste, and a silicon glue.

17. A method for fabricating a semiconductor device, the method comprising:
providing a cooling element comprising an inlet, an outlet, a cavity between the inlet and the outlet, and an opening through the cooling element to the cavity, the opening having a sidewall;
coupling a semiconductor chip to a base plate; and
coupling the base plate to the cooling element such that a first portion of the base plate extends into the opening and a second portion of the base plate extends over the sidewall of the opening.

18. The method of claim 17, further comprising:
arranging a sealant on one of the cooling element and the base plate prior to coupling the base plate to the cooling element.

19. The method of claim 18, wherein arranging the sealant comprises arranging one of an O-ring, a gasket, a silicon paste, and a silicon glue around the opening through the cooling element.

20. The method of claim 17, comprising coupling the base plate to the cooling element such that pins extending from the first portion of the base plate extend into the cavity of the cooling element.
